(19) United States
(12) Patent Application Publication
(10) Pub. No.: US 2011/0284163 A1
(43) Pub. Date: Nov. 24, 2011

(54) PLASMA PROCESSING APPARATUS

(76) Inventors: Jun-Ho Yoon, Suwon-si (KR); Kyoung-Sub Shin, Seongnam-si (KR); Woo-Seok Kim, Hwaseong-si (KR); Dong-Kwon Kim, Yongin-si (KR); Hyung-Yong Kim, Cheongju-si (KR); Yong-Ho Jeon, Hwaseong-si (KR)

(21) Appl. No.: 13/086,475

(22) Filed: Apr. 14, 2011

(30) Foreign Application Priority Data
May 19, 2010 (KR) 10-2010-0046837

(51) Int. Cl. H01L 21/00; C23F 1/08

(52) U.S. Cl. 156/345.24; 156/345.1

(57) ABSTRACT

A plasma processing apparatus includes a chamber for processing a substrate. A plasma generator is provided to generate plasma within the chamber. A window is provided in a sidewall of the chamber, and the window transmits light from the plasma within the chamber. A photocatalytic layer is provided on an inner surface of the window such that the photocatalytic layer is activated as a result of exposure to light from the plasma to decompose a residual product on the inner surface of the window.

### CROSS-REFERENCE TO RELATED APPLICATION

This application claims priority under 35 U.S.C. §119 to Korean Patent Application No. 10-2010-0046837, filed on May 19, 2010, the entire disclosure of which is hereby incorporated by reference herein in it's entirety.

### BACKGROUND

1. Technical Field

Example embodiments relate to a plasma processing apparatus. More particularly, example embodiments relate to a plasma processing apparatus including a chamber window for monitoring the plasma process.

2. Description of the Related Art

Semiconductor devices may be required to have rapid operational speeds as well as high capacitances. To meet the above requirements, the semiconductor devices are being developed to increase the degree of integration, reliability and response speeds thereof. Especially, as the semiconductor devices are highly integrated, a design rule of the semiconductor device may be reduced. The semiconductor device may be manufactured by various unit processes such as, for example, a photolithography process, a deposition process, an etching process, a planarization process, a cleaning process, a detection process, etc.

Especially, most of the unit processes such as an etching process and a deposition process may be performed under a high temperature. In these high-temperature processes, fine patterns in the semiconductor device may likely be deteriorated. Recently, to reduce the temperature of the process, plasma, called the fourth state of matter, may be used in the manufacturing process of the semiconductor device.

When a plasma process is performed on a film on a substrate, a residual product may be adsorbed frequently on an inner surface of a chamber of a plasma processing apparatus. For example, when a plasma etching process is performed, light from plasma may be detected to determine the detect end point in the plasma etching process. That is, the transmitted light through a chamber window may be analyzed for monitoring the plasma process.

However, the residual product such as a polymer that is formed during the plasma etching process may be adsorbed on the inner surface of the chamber as well as the chamber window. Thus, as the plasma etching process progresses, the residual product on the window may gradually decrease the light transmittance of the chamber window to thereby drop the sensitivity of the optical signal.

### SUMMARY

Example embodiments provide a plasma processing apparatus capable of precisely and sustainably monitoring the plasma process.

According to example embodiments, a plasma processing apparatus includes a chamber for processing a substrate. A plasma generator is provided to generate plasma within the chamber. A window is provided in a sidewall of the chamber, and the window transmits light from the plasma within the chamber. A photocatalytic layer is provided on an inner surface of the window such that the photocatalytic layer is activated as a result of exposure to light from the plasma to decompose a residual product on the inner surface of the window.

In example embodiments, the photocatalytic layer may absorb a specific wavelength of light from the plasma within the chamber to form radicals capable of decomposing the residual product.

In example embodiments, the photocatalytic layer may include titanium dioxide (TiO₂).

In example embodiments, the photocatalytic layer may include tungsten oxide (WO₃).

In example embodiments, the thickness of the photocatalytic layer may range from about 10 μm to about 100 μm.

In example embodiments, the photocatalytic layer may include a plurality of patterns of a mesh-type shape.

In example embodiments, the pattern of the photocatalytic layer may have a width of about 10 μm to about 100 μm.

In example embodiments, a wet etching process may be performed on the photocatalytic layer to form the patterns.

In example embodiments, the plasma processing apparatus may further include an analyzing unit for analyzing the transmitted light from the plasma to monitor the plasma etching process.

In example embodiments, the analyzing unit may include optical emission spectrometer.

According to example embodiments, a plasma processing apparatus may include a window in a sidewall of a chamber and a photocatalytic layer on an inner surface of the window. The photocatalytic layer may be activated as a result of exposure to light from plasma within the chamber to decompose a residual product on the window.

According to example embodiments, a plasma processing apparatus includes a chamber for processing a substrate, a plasma generator including a gas introducing portion for introducing a gas into the chamber and a high frequency generator for generating plasma within the chamber. The high frequency generator includes an upper electrode provided on an upper portion of the chamber, a source power supplier connected to the upper electrode to supply source power to the upper electrode, a lower electrode provided on a bottom portion of the chamber and a bias power supplier connected to the lower electrode to supply bias power to the lower electrode. The plasma processing apparatus further includes a view port penetrating a sidewall of the chamber, a window provided in the view port in the sidewall of the chamber, with the window transmitting light from the plasma within the chamber, a photocatalytic layer formed on an inner surface of the window that faces an inside of the chamber, and an analyzing unit for analyzing the transmitted light from the window to monitor a plasma process in the chamber. The analyzing unit includes a plasma analyzer, an optical cable, and an optical probe connected to the plasma analyzer by the optical cable and connected to the view port. In addition, the plasma processing apparatus further includes a gas exhauster including a vacuum pump connected to a side portion of the chamber for evacuating a gas or a residual product from the chamber.

Accordingly, with example embodiments of the present invention, the residual product generated during a plasma processing process may be prevented from being adsorbed on the inner surface of the window, to thereby precisely and sustainably monitor the plasma process and increase the sensitivity of the optical signal from the window.

### BRIEF DESCRIPTION OF THE DRAWINGS

Example embodiments can be more clearly understood from the following detailed description taken in conjunction with the accompanying drawings in which:

FIG. 1 is a cross-sectional view illustrating a plasma processing apparatus in accordance with an example embodiment.

FIG. 2 is an enlarged view illustrating a window of the plasma processing apparatus in FIG. 1.

FIG. 3 is a plan view illustrating a portion of a photocatalytic layer pattern on a window of a plasma processing apparatus in accordance with an example embodiment.

FIGS. 4A to 4C are cross-sectional views illustrating the photocatalytic layer in FIG. 3.

### DETAILED DESCRIPTION OF EXAMPLE EMBODIMENTS

Various example embodiments will be described more fully hereinafter with reference to the accompanying drawings, in which example embodiments are shown. Example embodiments may, however, be embodied in many different forms and should not be construed as limited to example embodiments set forth herein. It will be understood that when an element or layer is referred to as being “on,” “connected to” or “coupled to” another element or layer, it can be directly on, connected or coupled to the other element or layer or intervening elements or layers may be present. Like numerals refer to like elements throughout.

Hereinafter, example embodiments will be explained in detail with reference to the accompanying drawings.

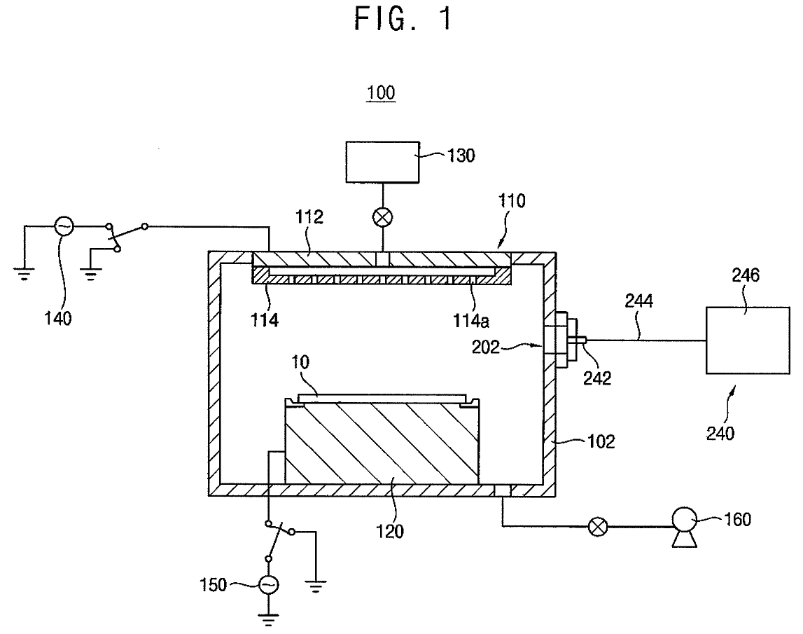

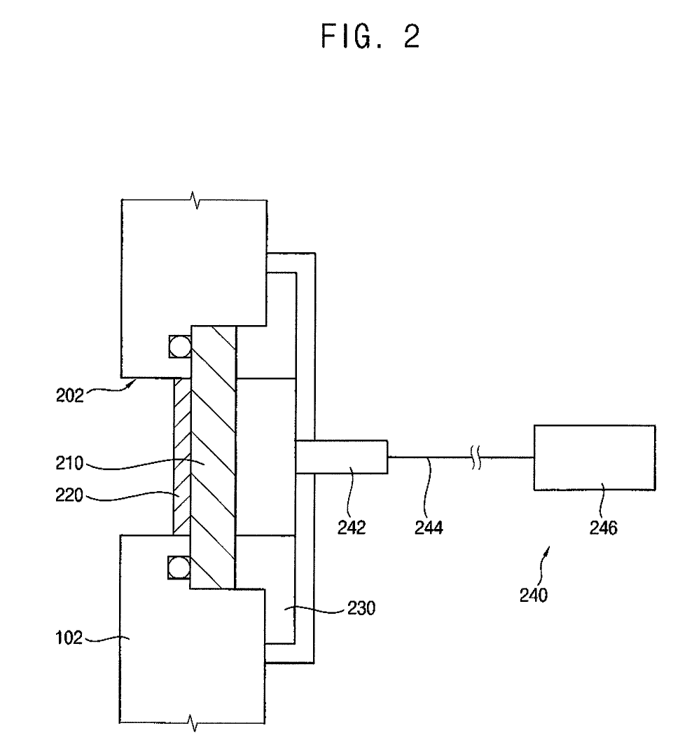

FIG. 1 is a cross-sectional view illustrating a plasma processing apparatus in accordance with an example embodiment. FIG. 2 is an enlarged view illustrating a window of the plasma processing apparatus in FIG. 1.

Referring to FIGS. 1 and 2, a plasma processing apparatus 100 according to an example embodiment includes, for example, a chamber 102, a plasma generator, a window 210 in a sidewall of the chamber 102 and a photocatalytic layer 220 on a surface of the window 210.

In an example embodiment, the plasma generator may generate plasma within the chamber 102 using, for example, plasma power (RF power). The plasma generator may include, for example, a gas introducing portion 130 and a high frequency generator. The high frequency generator may supply high frequency power to gas within the chamber 102 to generate plasma within the chamber 102. The high frequency generator may include, for example, an upper electrode 110, a source power supplier 140, a lower electrode 120 and a bias power supplier 150.

The upper electrode 110 may be provided in an upper portion of the chamber 102. The upper electrode 110 may include a first electrode 112 and a second electrode 114. The second electrode 114 may be positioned under the first electrode 112 and may be connected to a lower surface of the first electrode 112. For example, the first electrode 112 may have a disk shape and the second electrode 114 may have a shape corresponding to the first electrode 112. The source power supplier 140 may be connected to the upper electrode 110 by a first switch to supply source power to the first electrode 112.

The lower electrode 120 may be provided on a bottom of the chamber 102. A semiconductor substrate 10 may be supported on an upper surface of the lower electrode 120. The lower electrode 120 may support the semiconductor substrate 10 on the upper surface using, for example, vacuum absorption force or electrostatic force. The bias power supplier 150 may be connected to the lower electrode 120 by a second switch to supply bias power to the lower electrode 120.

However, it may be understood that the high frequency generator should not be construed as limited to the above-mentioned construction and the high frequency generator may have various configurations for plasma processing.

A gas exhauster may be provided in a side portion of the chamber 102. The gas exhauster may include, for example, a vacuum pump 160 that is connected to the chamber 102. The gas exhauster may evacuate gas or a residual product from chamber 102.

In an example embodiment, a view port 202 may be provided to penetrate the sidewall of the chamber 102. The window 210 may be provided in the view port 202. The window 210 may include, for example, a transparent material such as quartz. The window 210 may be hermetically sealed with, for example, an O-ring in the view port 202. Accordingly, the window 210 may transmit light from plasma within the chamber 102.

The plasma processing apparatus 100 may further include, for example, an analyzing unit 240 for analyzing the transmitted light from the window 210 to monitor a plasma process in the chamber 102.

For example, the analyzing unit 240 may include an optical probe 242, an optical cable 244 and a plasma analyzer 246. The optical probe 242 may be connected to the view port 202. The probe 242 may be connected to the plasma analyzer 246 by the optical cable 244.

The plasma analyzer 246 may analyze the transmitted light from the view port 202 of the chamber 102, the optical probe 242 and the optical cable 244. For example, the plasma analyzer 246 may include an optical emission spectrometer (OES).

While a plasma process is performed on a film on the semiconductor substrate 10, the chemical composition of plasma may be changed based on the composition of a material remaining in the chamber 102. That is, spectrums of light from plasma may be changed according to a change of a reactant in the chamber 102. Accordingly, the spectrums of the transmitted light from plasma may be analyzed by the OES to detect the composition of the material remaining in the chamber 102.

In an example embodiment, the photocatalytic layer may be formed on an inner surface of the window 210 that faces the inside of the chamber 102. The photocatalytic layer may be activated as a result of exposure to light from plasma within the chamber 102 to decompose a residual product that is adsorbed on the inner surface of the window 210.

The photocatalytic layer 220 may be formed using, for example, a transparent photocatalytic material having a high hardness. The photocatalytic layer 220 may be, for example, an anti-diffused reflection layer. Examples of the photocatalytic material may be metal oxide, sulfide compound, etc.

In this embodiment, when the photocatalytic layer 220 absorbs a specific wavelength of light from plasma within the chamber 102, the photocatalytic layer 220 may be activated to form radicals capable of decomposing the residual product that is formed during the plasma process.

The photocatalytic material may be excited to produce pairs of electrons and holes when illuminated by light. That is, the excess energy of the excited electron promotes the electron from the valence band to the conduction band to create the negative-electron (e−) and positive-hole (h+) pair. The positive-hole may break apart a water molecule to form a hydroxyl radical. The hydroxyl radical may serve as an oxidation agent to decompose an organic material such as, for example, a polymer that is formed within the chamber 102 during a process such as, for example, a plasma etching process.

For example, the photocatalytic layer 220 may include titanium dioxide (TiO₂) tungsten oxide (WO₃), cadmium sulfide (CdS), strontium titanium oxide (SrTiO₂), molybdenum disulfide (MoS₂), etc. The photocatalytic layer 220 may be activated when illuminated by, for example, ultraviolet light. The wavelength of the light may range from, for example, about 300 nm to about 400 nm.

The thickness range of the photocatalytic layer 220 may be selected to the extent that the photocatalytic layer 220 does not degrade the sensitivity of the optical signal through the window 210. For example, the thickness may range from about 10 μm to about 100 μm. Accordingly, the OES of the plasma analyzer 246 may analyze the transmitted light from the photocatalytic layer 220 and the window 210.

According to an example embodiment, when the photocatalytic layer 220 on the window 210 absorbs light from plasma, the photocatalytic reaction of the photocatalytic layer 220 may be applied for the reduction or elimination of a residual product that is deposited during a process such as, for example, a plasma etching process. Accordingly, the residual product adsorbed on the inner surface of the window 210 may be decomposed by the photocatalytic reaction, to thereby remove pollutants on the window 210.

Thus, the photocatalytic layer 220 may be formed on the window 210 of the plasma processing apparatus, to thereby improve the sensitivity of the OES for the processing monitoring or the semiconductor equipment maintenance.

Hereinafter, a method of performing a plasma etching process using the plasma processing apparatus 100 in FIG. 1 will be explained.

First, a substrate 10 having a film formed thereon is loaded into a chamber 102. An inactive gas and an etching gas are introduced into the chamber 102. Then, plasma power is applied to the chamber 102 to form plasma and the etching gas is activated to perform an etching process. Since the plasma etching gas is used to etch the film, a pattern with a beneficial profile may be formed on the substrate 10.

During the plasma etching process, light from plasma is transmitted to outside through the window 210 in the sidewall of the chamber 102. That is, the light from plasma is transmitted to the analyzing unit 240 through the photocatalytic layer 220 and the window 210. The analyzing unit 240 may analyze the transmitted light from plasma to monitor the plasma etching process.

As the plasma etching process is performed on the substrate 10, a residual product such as, for example, a polymer may be generated within the chamber 102. The residual product may be adsorbed on the inner wall of the chamber 102. The residual process may be adsorbed on the inner surface of the window 210. In this embodiment, the photocatalytic layer 220 may be activated as a result of exposure to light from plasma within the chamber 102 to decompose the residual product on the inner surface of the window 210.

Accordingly, the polymer generated during the etching process may be prevented from being adsorbed on the window 210, to thereby precisely monitor the etching process. Further, the photocatalyst layer 220 may not be changed itself or be consumed in the chemical reaction. Accordingly, the photocatalytic layer 220 may be formed on the window 210 of the plasma processing apparatus, to thereby increase the sensitivity of the OES for the sustainable processing monitoring or the semiconductor equipment maintenance.

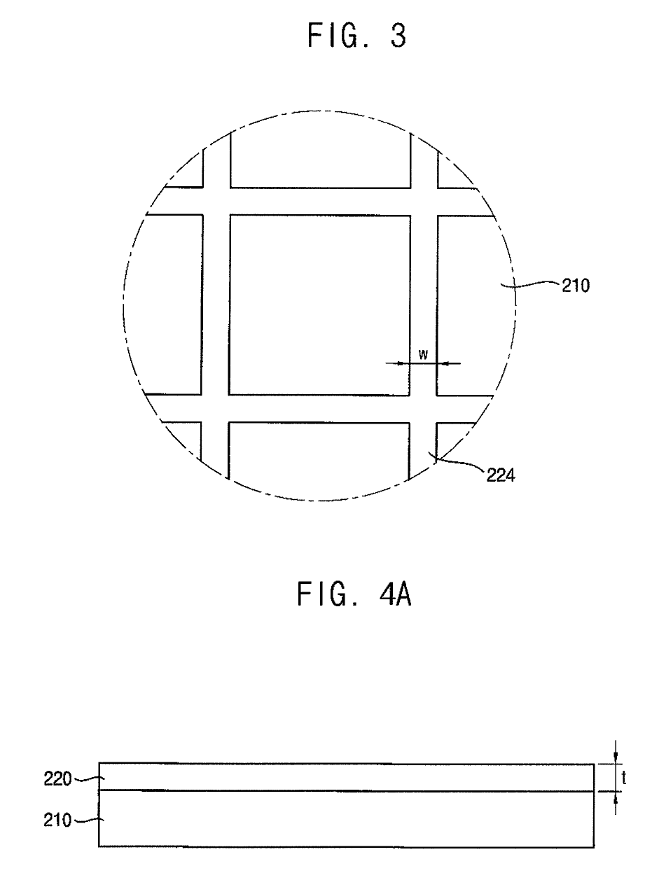

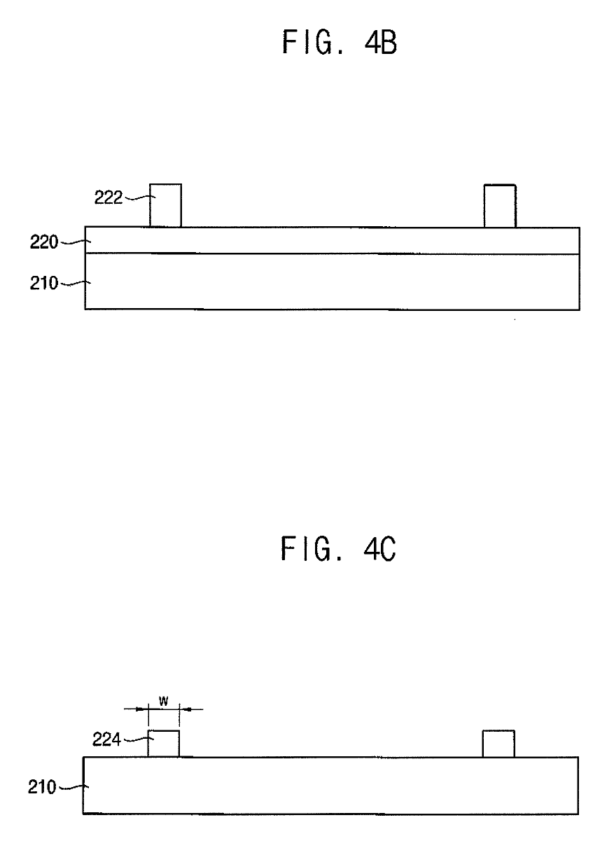

FIG. 3 is a plan view illustrating a portion of a photocatalytic layer pattern on a window of a plasma processing apparatus in accordance with another example embodiment. FIGS. 4A to 4C are cross-sectional views illustrating a method of forming the photocatalytic layer in FIG. 3. The present embodiment is substantially the same as in the embodiment of FIG. 1 except for a shape of the photocatalytic layer. Thus, the same reference numerals will be used to refer to the same or like elements as those described in the embodiment of FIG. 1 and any further repetitive explanation concerning the above elements will be omitted.

Referring to FIG. 3, in another example embodiment, a plasma processing apparatus may include a photocatalytic layer pattern 224 of, for example, a mesh-type shape on a window 210.

Because the photocatalytic layer pattern 224 is arranged in a mesh-type shape on the window 210, the photocatalytic layer pattern 224 may partially cover the window 210. Accordingly, the window 210 may be partially exposed by the photocatalytic layer pattern 224. Thus, the photocatalytic layer pattern 224 having a mesh-type shape may maximize the light transmittance of the window 210 and optimize the reduction or elimination of a residual product on the window 210 by photocatalytic reaction.

For example, the photocatalytic layer pattern 224 may have a width of about 10 μm to about 100 μm. The photocatalytic layer pattern 224 may have, for example, a plurality of polygonal patterns repeatedly arranged in a regular configuration. The polygonal pattern may have, for example, a rectangular shape, a triangular shape, etc. The shapes and the dimensions of the photocatalytic layer pattern 224 may be selected based on the light transmittance of the window 210 and the efficiency of photocatalytic reaction.

Hereinafter, a method of forming the photocatalytic layer in FIG. 3 will be explained.

Referring to FIG. 4A, a window 210 is installed in a view port 202 in a sidewall of a chamber 102. The window 210 may include, for example, a transparent material such as quartz.

Then, a photocatalytic layer 220 is formed on the window 210. For example, the photocatalytic layer 220 may be formed using a transparent photocatalytic material having a high hardness. The photocatalytic layer 220 may be, for example, an anti-diffused reflection layer. Examples of the photocatalytic material may be metal oxide, sulfide compound, etc.

For example, the photocatalytic layer 220 may include titanium dioxide (TiO₂) tungsten oxide (WO₃), etc.

The thickness (t) of the photocatalytic layer 220 may be selected to the extent that the photocatalytic layer 220 does not degrade the sensitivity of the optical signal through the window 210. For example, the thickness may range from about 10 μm to about 100 μm.

Referring to FIG. 4B and 4C, a photoresist pattern 222 is formed on the photocatalytic layer 220. The photocatalytic layer 220 may be selectively removed, for example, using the photoresist pattern 222 to form a photocatalytic layer pattern 224 having a mesh-type shape. Then, the photoresist pattern 222 may be removed by, for example, an ashing process or strip process.

In another example embodiment, the photocatalytic layer 222 may be etched by, for example, a wet etching process. The wet etching process may be performed using, for example, a diluted etching solution (for example, BOE (buffered oxide etchant)).

For example, the photocatalytic layer pattern 224 may have a plurality of polygonal patterns repeatedly arranged in a regular configuration. The width (W) of the photocatalytic layer pattern 224 may be selected based on the light transmittance o the window 210 and the efficiency of photocatalytic reaction. Accordingly, the photocatalytic layer pattern 224 having a mesh-type shape may maximize the light transmittance of the window 210 and optimize the reduction or elimination of a residual product on the window 210 by photocatalytic reaction.

As mentioned above, a plasma processing apparatus according to example embodiments includes a window in a sidewall of a chamber and a photocatalytic layer on an inner surface of the window. The photocatalytic layer may be activated as a result of exposure to light from plasma within the chamber to decompose a residual product on the window.

Accordingly, the residual product generated during the etching process may be prevented from being adsorbed on the inner surface of the window, to thereby precisely and sustainably monitor the etching process and increase the sensitivity of the optical signal.

Having described the exemplary embodiments of the present invention, it is further noted that it is readily apparent to those of reasonable skill in the art that various modifications can be made herein without departing from the spirit and scope of the invention as defined by the metes and bounds of the appended claims.

What is claimed is:

1. A plasma processing apparatus, comprising:
a chamber for processing a substrate;
a plasma generator for generating plasma within the chamber;
a window in a sidewall of the chamber, the window transmitting light from the plasma within the chamber; and
a photocatalytic layer on an inner surface of the window such that the photocatalytic layer is activated as a result of exposure to light from the plasma to decompose a residual product on the inner surface of the window.

2. The plasma processing apparatus of claim 1, wherein the photocatalytic layer absorbs a specific wavelength of light from the plasma within the chamber to form radicals capable of decomposing the residual product.

3. The plasma processing apparatus of claim 2, wherein the photocatalytic layer comprises titanium dioxide (TiO₂).

4. The plasma processing apparatus of claim 2, wherein the photocatalytic layer comprises tungsten oxide (WO₃).

5. The plasma processing apparatus of claim 1, wherein the thickness of the photocatalytic layer ranges from about 10 μm to about 100 μm.

6. The plasma processing apparatus of claim I, wherein the photocatalytic layer includes a plurality of patterns of a mesh-type shape.

7. The plasma processing apparatus of claim 6, wherein the pattern of the photocatalytic layer has a width of about 10 μm to about 100 μm.

8. The plasma processing apparatus of claim 1, further comprising a gas exhauster including a vacuum pump connected to the chamber for evacuating a gas or a residual product from the chamber.

9. The plasma processing apparatus of claim 1, further comprising an analyzing unit for analyzing the transmitted light from the plasma to monitor the plasma etching process.

10. The plasma processing apparatus of claim 9, wherein the analyzing unit comprises an optical emission spectrometer.

11. A plasma processing apparatus comprising:
a chamber for processing a substrate;
a plasma generator including a gas introducing portion for introducing a gas into the chamber and a high frequency generator to generate plasma within the chamber, wherein the high frequency generator including an upper electrode provided on an upper portion of the chamber and a lower electrode provided on a bottom portion of the chamber;
a view port penetrating a sidewall of the chamber;
a window provided in the view port in the sidewall of the chamber, the window transmitting light from the plasma within the chamber;
a photocatalytic layer formed on an inner surface of the window that faces an inside of the chamber;
an analyzing unit for analyzing the transmitted light from the window to monitor a plasma process in the chamber, wherein the analyzing unit includes a plasma analyzer, an optical cable, and an optical probe connected to the plasma analyzer by the optical cable and connected to the view port; and
a gas exhauster including a vacuum pump connected to a side portion of the chamber for evacuating a gas or a residual product from the chamber.

12. The plasma processing apparatus of claim 11, wherein the upper electrode includes a first electrode and a second electrode positioned under the first electrode and connected to a lower surface of the first electrode and wherein a source power supplier is connected to the upper electrode by a first switch to supply source power to the first electrode.

13. The plasma processing apparatus of claim 12, wherein the first electrode has a disk shape and the second electrode has a shape corresponding to the first electrode.

14. The plasma processing apparatus 12, further comprising a semiconductor substrate supported on an upper surface of the lower electrode and wherein a bias power supplier is connected to the lower electrode by a second switch to supply bias power to the lower electrode.

15. The plasma processing apparatus of claim 11, wherein the window is formed of quartz and the window is hermetically sealed with an O-ring in the view port.

16. The plasma processing apparatus of claim 11, wherein the photocatalytic layer absorbs a specific wavelength of light from the plasma within the chamber to form radicals capable of decomposing the residual product.

17. The plasma processing apparatus of claim 11, wherein the photocatalytic layer is composed of one of a metal oxide and a sulfide compound and wherein the thickness of the photocatalytic layer ranges from about 10 μm to about 100 μm.

18. The plasma processing apparatus of claim 11, wherein the photocatalytic layer includes one of a material selected from the group consisting of titanium dioxide (TiO₂) tungsten oxide (WO₃), cadmium sulfide (CdS), strontium titanium oxide (SrTiO₂), and molybdenum disulfide (MoS₂).

19. The plasma processing apparatus of claim 11, wherein the photocatalytic layer includes a plurality of patterns of a mesh-type shape on the window, wherein the plurality of patterns of the photocatalytic layer partially cover the window such that the window is partially exposed by the plurality of patterns of the photocatalytic layer .

20. The plasma processing apparatus of claim 11, wherein the plasma analyzer of the analyzing unit comprises an optical emission spectrometer.
